(19) United States
(12) Patent Application Publication
(10) Pub. No.: US 2012/0183689 A1
(43) Pub. Date: Jul. 19, 2012

(54) NI FILM FORMING METHOD

(75) Inventors: Mikio Suzuki, Nirasaki-shi (JP); Takashi Nishimori, Nirasaki-shi (JP); Hideki Yuasa, Nirasaki-shi (JP)

(73) Assignee: TOKYO ELECTRON LIMITED, Tokyo (JP)

(21) Appl. No.: 13/498,446

(22) PCT Filed: Sep. 28, 2010
(86) PCT No.: PCT/JP2010/066764

§ 371 Date: Mar. 27, 2012

(30) Foreign Application Priority Data
Sep. 29, 2009 (JP) 2009-223888

(51) Int. Cl. C23C 16/06; C23C 16/52; C23C 16/56

(52) U.S. Cl. 427/250

(57) ABSTRACT

A Ni film forming method performs a cycle once or multiple times. The cycle includes: forming a nitrogen-containing Ni film on a substrate by CVD using nickel amidinate as a film formation material and at least one selected from ammonia, hydrazine and derivatives thereof as a reduction gas; and eliminating nitrogen from the nitrogen-containing Ni film by atomic hydrogen which is generated by using as a catalyst Ni produced by supplying hydrogen gas to the nitrogen-containing Ni film.

### FIELD OF THE INVENTION

The present invention relates to a Ni film forming method for forming a Ni film by chemical vapor deposition (CVD).

### BACKGROUND OF THE INVENTION

Recently, there has been a demand for higher speed and lower power consumption of semiconductor devices. For example, in order to realize a low resistance of a gate electrode or contact portions of a source and a drain in a metal oxide semiconductor, silicide is formed by a salicide process. As for the silicide, nickel silicide (NiSi) which can reduce consumption of silicon and ensure a low resistance attracts attention.

When a NiSi film is formed, there is widely used a method in which a Ni film is form on a Si substrate or a polysilicon film by physical vapor deposition (PVD) such as sputtering or the like, and then the Ni film is annealed in an inert gas (see, e.g., Japanese Patent Application Publication No. H9-153616).

Further, the Ni film itself may be used for a capacitor electrode of DRAM.

However, such PVD method is disadvantageous in that step coverage is poor in terms of miniaturization of semiconductor devices. Therefore, there has been suggested a method for forming a Ni film by CVD which ensures a good step coverage (see, International Application Publication No. 2007/116982).

When a Ni film is formed by CVD, nickel amidinate can be preferably used as a film forming material (precursor). However, when a Ni film is formed by using nickel amidinate as a precursor, N is attracted into the film. Accordingly, nickel nitride (NiₓN) is formed during the formation of the Ni film. The film thus formed is a nitrogen-containing Ni film. Since impurities such as O (oxygen) and the like are also included in that film, the resistance of the film is increased.

### SUMMARY OF THE INVENTION

In view of the above, the present invention provides a Ni film forming method for forming a Ni film having small amount of impurities by using nickel amidinate as a film forming material.

In accordance with an aspect of the present invention, there is provided a Ni film forming method performing a cycle once or multiple times. The cycle includes forming a nitrogen-containing Ni film on a substrate by CVD using nickel amidinate as a film formation material and at least one selected from ammonia, hydrazine and derivatives thereof as a reduction gas; and eliminating nitrogen from the nitrogen-containing Ni film by atomic hydrogen which is generated by using as a catalyst Ni produced by supplying hydrogen gas to the nitrogen-containing Ni film.

In accordance with another aspect of the present invention, there is provided a computer-readable storage medium storing a computer-readable program for controlling a film forming apparatus to execute Ni film forming method performing a cycle once or multiple times. The cycle includes forming a nitrogen-containing Ni film on a substrate by CVD using nickel amidinate as a film formation material and at least one selected from ammonia, hydrazine and derivatives thereof as a reduction gas; and eliminating nitrogen from the nitrogen-containing Ni film by atomic hydrogen which is generated by using as a catalyst Ni produced by supplying hydrogen gas to the nitrogen-containing Ni film.

### BRIEF DESCRIPTION OF THE DRAWINGS

FIG. 1 is a schematic view showing an example of a film forming apparatus for performing a metal film forming method in accordance with an embodiment of the present invention.

FIG. 2 is a timing diagram showing a sequence of the metal film forming method.

FIG. 3A shows a relationship between the number of cycles and a resistivity of a Ni film formed on a Si wafer when a processing temperature is set to about 160° C.

FIG. 3B shows a relationship between the number of cycles and a resistivity of a Ni film formed on a SiO₂ wafer when a processing temperature is set to about 160.

FIG. 4 shows X-ray diffraction (XRD) patterns of a Ni film formed at a processing temperature of about 160° C. while varying the number of cycles.

FIG. 5 show SEM pictures of surfaces of a Ni film formed at a processing temperature of about 160° C. when the cycle is performed once, four times and ten times.

FIG. 6A shows a relationship between the number of cycles and a resistivity of a Ni film formed on a Si wafer at a processing temperature of about 200° C.

FIG. 6B shows a relationship between the number of cycles and a resistivity of a Ni film formed on a SiO₂ wafer at a processing temperature of about 200° C.

FIG. 7 show SEM pictures of surfaces of Ni films formed at a processing temperature of about 200° C. when the cycle is formed once, twice and four times.

FIG. 8 shows changes in the Ni peak intensity in the X-ray diffraction (XRF) pattern when a Ni film is formed on a SiO₂ film while varying a temperature.

FIG. 9 shows SEM pictures of surfaces of Ni films formed on a SiO₂ film while varying a temperature.

FIG. 10 shows a result of examining decrease of a resistivity Rs when H₂ treatment is performed while varying a temperature, a pressure and processing time.

### DETAILED DESCRIPTION OF THE EMBODIMENTS

Hereinafter, an embodiment of the present invention will be described with reference to the accompanying drawings.

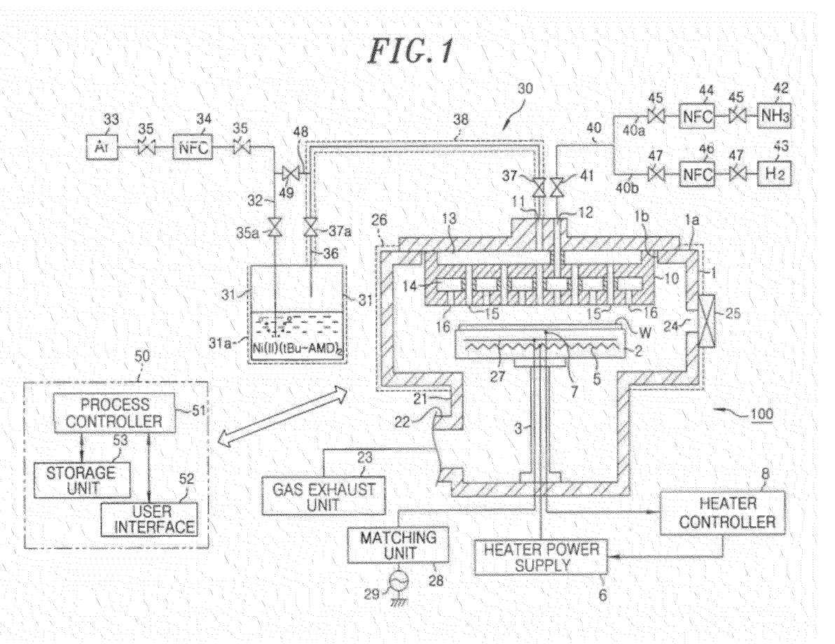

In the present embodiment, the case in which a nickel film is formed as a metal film will be described. FIG. 1 is a schematic view showing an example of a film forming apparatus for performing a metal film forming method in accordance with an embodiment of the present invention.

A film forming apparatus 100 includes a substantially cylindrical airtight chamber 1; a susceptor 2 provided in the chamber 1 for horizontally supporting a wafer W as a target substrate to be processed; and a cylindrical supporting member 3 which supports the susceptor 2, the supporting member 3 extending from a bottom portion of a gas exhaust section to be described later to a central portion of a bottom surface of the susceptor 2. The susceptor 2 is made of ceramic such as AlN or the like. Further, a heater 5 is buried in the susceptor 2, and a heater power supply 6 is connected to the heater 5.

Meanwhile, a thermocouple 7 is provided near a top surface of the susceptor 2, and a signal from the thermocouple 7 is transmitted to a heater controller 8. Moreover, the heater controller 8 transmits an instruction to the heater power supply 6 in accordance with the signal from the thermocouple 7 and controls heating of the heater 5 to adjust the temperature of the wafer W to a predetermined value.

A high frequency power application electrode 27 is installed above the heater 5 in the susceptor 2. A high frequency power supply 29 is connected to the electrode 27 via a matching unit 28. A plasma is generated by applying a high frequency power to the electrode 27 if necessary, and plasma CVD can be performed by using the plasma thus generated. Moreover, three wafer elevation pins (not shown) are provided at the susceptor 2 so as to project and retract with respect to the surface of the susceptor 2. The wafer elevation pins project from the surface of the susceptor 2 when the wafer W is transferred.

A circular opening 1b is formed at a ceiling wall 1a of the chamber 1, and a shower head 10 is fitted thereinto so as to project toward the interior of the chamber 1. The shower head 10 serves to inject a film forming source gas supplied from a gas supply mechanism 30 to be described later into the chamber 1, and includes at an upper portion thereof a first gas inlet path 11 through which nickel amidinate, e.g., Ni(II)N, N′-di-tertiarybutylamidinate (Ni(II)(tBu-AMD)₂), as a film forming material gas is introduced; and a second gas inlet path 12 through which NH₃ gas as a reduction gas or H₂ gas as a heat treatment gas is introduced into the chamber 1.

As for nickel amidinate, there may be employed Ni(II)N, N′-di-isoporpylamidinate (Ni(II)(iPr-AMD)₂); Ni(II)N, N′-di-ethylamidinate (Ni(II)(Et-AMD)₂); Ni(II)N, N′-di-methylamidinate (Ni(II)(Me-AMD)₂) or the like.

The interior of the shower head 10 is divided into an upper space 13 and a lower space 14. The upper space 13 is connected to the first gas inlet path 11, and a first gas discharge path 15 extends from the upper space 13 toward a bottom surface of the shower head 10. The lower space 14 is connected to the second gas inlet path 12, and a second gas discharge path 16 extends from the lower space 14 toward the bottom surface of the shower head 10. In other words, the shower head 10 is used to independently inject a Ni compound gas serving as a film forming material, and NH₃ gas or H₂ gas through the injection paths 15 and 16, respectively.

A gas exhaust section 21 projecting downward is provided at a bottom wall of the chamber 1. A gas exhaust line 22 is connected to a side surface of the gas exhaust section 21, and a gas exhaust unit 23 including a vacuum pump, a pressure control valve or the like is connected to the gas exhaust line 22. By operating the gas exhaust unit 23, the pressure in the chamber 1 can be reduced to a predetermined level.

Provided on a sidewall of the chamber 1 are a loading/unloading port 24 through which the wafer W is loaded and unloaded; and a gate valve 25 for opening and closing the loading/unloading port 24. In addition, a heater 26 is provided around a wall of the chamber 1, so that the temperature of an inner wall of the chamber 1 can be controlled during the film forming process.

The gas supply mechanism 30 includes a film forming material tank 31 storing therein, as a film forming material, nickel amidinate, e.g., Ni(II)N, N′-di-tertiarybutylamidinate Ni(II)(tBu-AMD)₂). A heater 31a is provided around the film forming material tank 31, so that the film forming material in the tank 31 can be heated to a proper temperature.

A bubbling line 32 through which Ar gas as a bubbling gas is supplied from above is inserted into the film forming material tank 31 to be immersed in the film forming material. An Ar gas supply source 33 is connected to the bubbling line 32, and a mass flow controller (MFC) 34 and valves 35 are provided in the bubbling line 32, the mass flow controller 34 being disposed between the valves 35.

A source gas feeding line 36 is inserted at one end into the film forming material tank 31 from above, and the other end of the source gas discharge line 36 is connected to the first gas inlet path 11 of the shower head 10. A valve 37 is provided in the source gas discharge line 36. A heater 38 for preventing condensation of the film forming material gas is provided in the source gas discharge line 36. By supplying a bubbling gas, e.g., Ar gas, to a film forming material in the film forming material tank 31, the film forming material is vaporized by bubbling, and a film forming material gas thus generated is supplied into the shower head 10 through the source gas discharge line 36 and the first gas inlet path 11.

The bubbling line 32 and the source gas discharge line 36 are connected to each other by a bypass line 48, and a valve 49 is disposed in the bypass line 48. Valves 35a and 37a are respectively disposed at downstream sides of the joint portions between the bypass line 48 and the bubbling line 32 and between the bypass line 48 the source gas discharge line 36. By closing the valves 35a and 37a and opening the valve 49, Ar gas from the Ar gas supply source can be supplied as a purge gas or the like into the chamber 1 through the bubbling line 32, the bypass line 48 and the source gas discharge line 36.

A line 40 is connected to the second gas inlet path 12 of the shower head 10, and a valve 41 is disposed in the line 40. The line 40 is branched into branch lines 40a and 40b. A NH₃ gas supply source 42 through which NH₃ gas as a reduction gas is supplied is connected to the branch line 40a, and the branch line 40b is connected to a H₂ gas supply source 43. Further, a mass flow controller (MFC) 44 as a flow rate controller and valves 45 are provided in the branch line 40a, the mass flow controller 44 being disposed between the valves 45. Similarly, a mass flow controller (MFC) 46 as a flow rate controller and valves 47 are provided in the branch line 40b, the mass flow controller 46 being disposed between the valves 47. As for the reduction gas, there may be employed hydrazine, NH₃ derivative, hydrazine derivative or the like, instead of NH₃.

When the plasma CVD is performed by applying a high frequency power to the electrode 27 if necessary, although they are not shown, it is preferable that an additional branch line is branched from the line 40a to provide an Ar gas supply source for supplying plasma ignition Ar gas through the additional branch line, a mass flow controller and valves being provided in the additional branch line with the mass flow controller disposed between the valves.

The film forming apparatus 100 further includes a control unit 50 for controlling the components, i.e., the valves, the power supply, the heaters, the pumps and the like. The control unit 50 includes a process controller 51 having a micro processor (computer), a user interface 52, and a storage unit 53. The components of the film forming apparatus 100 are electrically connected to and controlled by the process controller 51. The user interface 52 is connected to the process controller 51, and includes a keyboard through which an operator inputs commands for managing each component of the film forming apparatus, a display for visually displaying an operating state of each component of the film forming apparatus, and the like.

The storage unit 53 is also connected to the process controller 51, and stores therein a control program for implementing various processes to be performed in the film forming apparatus 100 under the control of the process controller 51 and/or another control program, i.e., process recipes, various database and the like, for implementing a predetermined process in each component of the film forming apparatus 100 in accordance with process conditions. The process recipes are stored in a storage medium (not shown) in the storage unit 53. The storage medium may be a fixed medium, such as a hard disk or the like, or a portable medium such as a CD-ROM, a DVD, a flash memory, or the like. Further, the recipes may be appropriately transmitted from another device through, e.g., a dedicated line.

If necessary, a desired process is performed in the film forming apparatus 100 under the control of the process controller 51 by reading a predetermined process recipe from the storage unit 53 in response to an instruction or the like from the user interface 52 and then executing the process recipe in the process controller 51.

Hereinafter, a method for forming a Ni film in accordance with another embodiment of the present invention which is performed by the film forming apparatus 100 will be described.

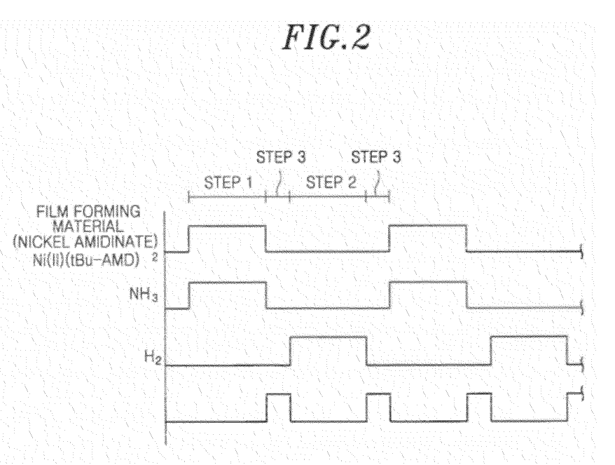

First, the gate valve 25 is opened, and a wafer W is loaded into the chamber 1 through the loading/unloading port 24 and mounted on the susceptor 2 by a transfer device (not shown). Next, the chamber 1 is exhausted by the gas exhaust unit 23 so that a pressure in the chamber 1 is set to a predetermined level. Then, the susceptor 2 is heated to a predetermined temperature. In that state, as shown in FIG. 2, a film forming process (step 1) for forming a nitrogen-containing Ni film by supplying nickel amidinate as a film forming material gas and a reduction gas and a denitrification process (step 2) for eliminating N from the nitrogen-containing Ni film by supplying H₂ gas to the nitrogen-containing Ni film are performed one cycle or two or more cycle repeatedly with a purge process (step 3) therebetween.

In the film forming process of the step 1, Ar gas as a bubbling gas is supplied to nickel amidinate, e.g., Ni(II)N, N′-di-tertiarybutylamidinate (Ni(II)(tBu-AMD)₂), as a film forming material stored in the film forming material tank 31. Accordingly, a Ni compound as a film forming material is vaporized by bubbling and then supplied into the chamber 1 through the source gas discharge line 36, the first gas inlet path 11 and the shower head 10. Further, NH₃ gas as a reduction gas is supplied into the chamber 1 from the NH₃ gas supply source 42 through the branch line 40a, the line 40, the second gas inlet path 12, and the shower head 10.

Here, as for the reduction gas, there may be employed hydrazine, NH₃ derivative, hydrazine derivative or the like, instead of NH₃. In other words, as for the reduction gas, there may be used at least one selected among NH₃, hydrazine, and derivatives thereof. As for ammonia derivative, monomethyl ammonium may be used, for example. As for the hydrazine derivative, monomethyl hydrazine or dimethyl hydrazine may be used, for example. Among them, ammonia is preferable. They serve as reducing agents having unshared electron pairs and easily react with nickel amidinate. Hence, a nitrogen-containing Ni film can be formed at a relatively low temperature.

The film forming reaction occurring at this time will be described hereinafter.

Nickel amidinate used as a film forming material, e.g., Ni(II)N, N′-di-tertiarybutylamidinate (Ni(II)(tBu-AMD)₂), has a structure shown in the following structural formula (1). In other words, amidinate ligands are coupled to Ni serving as a nucleus, and Ni exists substantially as Ni²⁺.

The reducing agent, e.g., NH₃, having an unshared electron pair is coupled to Ni²⁺ of nickel amidinate having the above structure which serves as a Ni nucleus, and is decomposed by the amidinate ligand. The reaction occurring at that time is considered as a nucleophilic substitution reaction of NH₃ with the Ni nucleus, in which NiₓN (x is 3 or 4) is generated as a nitrogen-containing Ni compound having a high reactivity. Accordingly, by supplying nickel amidinate and a reduction gas, e.g., NH₃, into the chamber 1, a film mainly made of NiₓN is formed, on the surface of the wafer W heated by the susceptor 1, by thermal CVD based on the above reaction.

Due to high reactivity of the film forming reaction, the film formation can be performed at a low temperature. The wafer temperature at that time is preferably set in a range from about 160° C. to 200° C. When the wafer temperature is set to be lower than about 160° C., the film forming reaction is slow and the sufficient film forming rate is not obtained. When the wafer temperature is set to be higher than about 200° C., the film may be agglomerated.

The other conditions are set as follows: a pressure in the chamber 1 is preferably set in a range from about 133 Pa to 665 Pa (1 Torr to 5 Torr); a flow rate of Ar gas is preferably set in a range from about 100 mL/min(sccm) to 500 mL/min(sccm); and a flow rate of NH₃ gas as a reduction gas is preferably set in a range from about 400 mL/min(sccm) to 4500 mL/min(sccm). Further, a thickness of a Ni film formed by a single film forming process preferably ranges from about 2 nm to 20 nm. Accordingly, denitrification using H₂ gas in the step 2 is easily carried out. The time for a single film forming process is properly determined depending on a film thickness of a film to be formed.

In the step 1, in order to assist the film forming reaction, a Ni film may be formed by plasma CVD by applying a high frequency power from the high frequency power supply 29 to the electrode 27 in the susceptor 2, if necessary.

Upon completion of the film forming process of the step 1, the purge process of the step 3 is carried out. In the step 3, the supply of the Ni compound gas and the NH₃ gas is stopped by closing the valves 35a, 37a, 41 and 45. Then, while high-speed evacuation is performed by the gas exhaust unit 23, the valve 49 is opened and the interior of the chamber 1 is purged by supplying Ar gas into the chamber 1 through the bypass line 48 and the source gas discharge line 36. The flow rate of the Ar gas at that time is preferably set from about 1000 mL/min(sccm) to 5000 mL/min(sccm). The purge process is preferably performed for a time period ranging from about 5 to 20 seconds.

As described above, N and impurities such as O (oxygen) and the like exist in the film formed in the step, so that the resistivity of the formed film becomes increased. Thus, in the denitrification process (H₂ treatment) of the step 1, N is eliminated from the film formed in the step 1 by supplying H₂ gas. At this time, the impurities such as O and the like are removed. Therefore, it is possible to obtain a Ni film having a good film quality and a low resistivity.

Hereinafter, the mechanism of the denitrification process will be described.

Microscopically, the film formed in the step 1 has a structure in which an N atom is surrounded by a plurality of Ni atoms. Therefore, when the H₂ treatment is performed in-situ after the film forming process and the purge process, there occurs the reaction in which H₂ gas supplied to the film is converted into atomic hydrogen by using Ni in the film as a catalyst. Due to the significantly high reactivity of the atomic hydrogen, N can be rapidly eliminated from the film by reaction with Ni in the film. At this time, the impurities such as O and the like are also rapidly removed by reaction with the atomic hydrogen.

The elimination of N from NiₓN is achieved by heating at about 300° C. without performing H₂ treatment. However, such heating causes agglomeration of Ni and hinders formation of a continuous film. This is because, since Ni forms clusters at about 300° C. and Ni clusters are bonded to each other by N, the elimination of N hinders formation of Ni—Ni bond in the grain boundary of the Ni clusters, which results in separation of the Ni clusters.

However, in the H₂ treatment of the step 2, N can be sufficiently eliminated from the film even at a temperature lower than or equal to about 200° C. and, thus, an Ni film having a good surface state can be formed without agglomeration of Ni.

When the H₂ treatment of the step 2 is performed, the wafer W is heated by the susceptor 2 after the purge process. Further, H₂ gas is supplied into the chamber 1 by opening the valves 41 and 47 in a state where Ar gas is supplied into the chamber 1 at a flow rate from about 1000 mL/min(sccm) to 3000 mL/min(sccm) or the supply of Ar gas is stopped by closing the valve 49.

At this time, the flow rate of H₂ gas is preferably set in a range from about 1000 mL/min(sccm) to 4000 mL/min(sccm). The reactivity becomes increased as the wafer temperature is raised. However, as described above, the denitrification reaction sufficiently occurs at a temperature lower than about 200° C., and the agglomeration of the film does not occur at the temperature of about 200° C. or less. On the other hand, when the wafer temperature is set to be lower than about 160° C., the reactivity is decreased and the processing time is increased. Therefore, as in the case of the temperature in the film forming process, it is preferably set the wafer temperature in the range from about 160° C. to 200° C. Further, the wafer temperature is preferably set to be equal to that in the film forming process of the step 1.

Hence, the heating temperature of the susceptor 2 can be maintained at a constant level throughout the processes, which increases a throughput. The pressure in the chamber 1 is preferably set in a range from about 400 Pa to 6000 Pa (3 Torr to 45 Torr) in a state where the supply of Ar gas is stopped. Within the desired temperature and pressure ranges in the step 2, it is preferable to increase the temperature and the pressure. The H₂ treatment of the step 2 is preferably performed for a time period ranging from about 180 sec to 1200 sec.

Thereafter, the purge process of the step 3 is performed, and the film forming process may be completed. However, it is preferable to repeat the cycle including Ni film formation, purging, H₂ treatment and purging multiple times. Accordingly, the effect of removing impurities can be further increased. In other words, when the cycle is repeated multiple times, a thin Ni film is formed and, then, denitrification is carried out in a H₂ gas atmosphere. Therefore, the impurities are easily removed from the film.

As the number of cycles is raised, the effect of removing impurities is increased, and the resistivity is decreased. However, when the number of cycles is excessively raised, the total film formation time is increased. For that reason, the cycle is preferably repeated from 2 to 10 times, and more preferably from 4 to 10 times. In view of the same aspect, a film thickness obtained by one cycle preferably ranges from about 2 nm to 5 nm. In order to effectively remove the impurities from the film, time for the nitrification process in an H₂ gas atmosphere needs to be increased. However, when the nitrification time is excessively increased, a throughput is decreased. Therefore, as described above, the H₂ treatment time is preferably set in a range from about 180 sec to 1200 sec.

After the final purge process is completed, the wafer W subjected to the film formation is unloaded through the loading/unloading port 24 by a transfer device (not shown) by opening the gate valve 25.

By performing the cycle including a step of forming a nitrogen-containing Ni film on a wafer as a substrate by CVD by using nickel amidinate as a film forming material and NH₃ or the like as a reduction gas and a denitrification step of eliminating N from the film by supplying H₂ gas once or a plurality of times, N and other impurities can be rapidly removed from the film, and a Ni film having a small number of impurities can be obtained.

Hereinafter, test results showing the effect of the present invention and the procedures which have resulted in the present invention will be described.

Here, a Ni film having a predetermined thickness was formed by the film forming apparatus shown in FIG. 1 on a wafer (SiO₂ wafer) in which a th-SiO₂ film (thermal oxide film) having a thickness of about 100 nm was formed on a silicon substrate having a diameter of about 300 mm and on a wafer (Si wafer) in which a surface of a silicon substrate was cleaned by dilute hydrofluoric acid, by performing a cycle including film formation (step 1), purging (step 3), H₂ treatment (step 2) and purging (step 3) a predetermined number of times.

In the film forming process of the step 1, a Ni film was formed by CVD. At this time, a pressure in the chamber was set to about 665 Pa (5 Torr), and a film forming material, e.g., Ni(II)N, N′-di-tertiarybutylamidinate (Ni(II)(tBu-AMD)₂), was stored in the film forming material tank 31. The temperature of the film forming material was maintained at about 95° C. by the heater 31a, and Ar gas was supplied at a flow rate of about 100 mL/min(sccm). Ni(II)(tBu-AMD)₂ gas was supplied into the chamber 1 by bubbling, and NH₃ gas was supplied from the NH₃ gas supply source 42 at a flow rate of about 800 mL/min(sccm).

In the H₂ treatment of the step 2, a pressure in the chamber was set to about 400 Pa (3 Torr), and H₂ gas was supplied at a flow rate of about 3000 mL/min(sccm).

The wafer temperature in the step 1 was equal to that in the step 2. The test was performed while setting the wafer temperature to about 160° C. and 200° C.

In the test in which the wafer temperature was set to about 160° C., the number of cycles was set to 1, 2, 4, 10 and 20, and a target film thickness was set to about 20 nm. The film formation time in the step 1 and the target film thickness obtained by a single process were respectively set to about 590 sec and about 20 nm in the case of performing the cycle once; about 350 sec and about 10 nm in the case of performing the cycle twice; about 210 sec and about 5 nm in the case of performing the cycle four times; about 100 sec and about 2 nm in the case of performing the cycle ten times; and about 60 sec and about 1 nm in the case of performing the cycle twenty times. The H₂ treatment time was set to about 180 sec and 1200 sec in the case of performing the cycle once, twice and four times, and about 1200 sec only in the case of performing the cycle ten times and twenty times.

In the test in which the wafer temperature was set to about 200° C., the number of cycles was set to 1, 2 and 4, and a target film thickness was set to about 20 nm. The film formation time in the step 1 and the target film thickness obtained by a single process were respectively about 290 sec and about 20 nm in the case of performing the cycle once; about 175 sec and about 10 nm in the case of performing the cycle twice; and about 110 sec and about 5 nm in the case of performing the cycle four times. Moreover, the H₂ treatment time was set to about 1200 sec only.

In the above tests, the resistivities were measured, and the scanning electron microscope (SEM) pictures of the surfaces were obtained. When the test was performed by setting the temperature of the SiO₂ wafer which does not react with underlying silicon to about 160° C., the X-ray diffraction (XRD) measurement was performed.

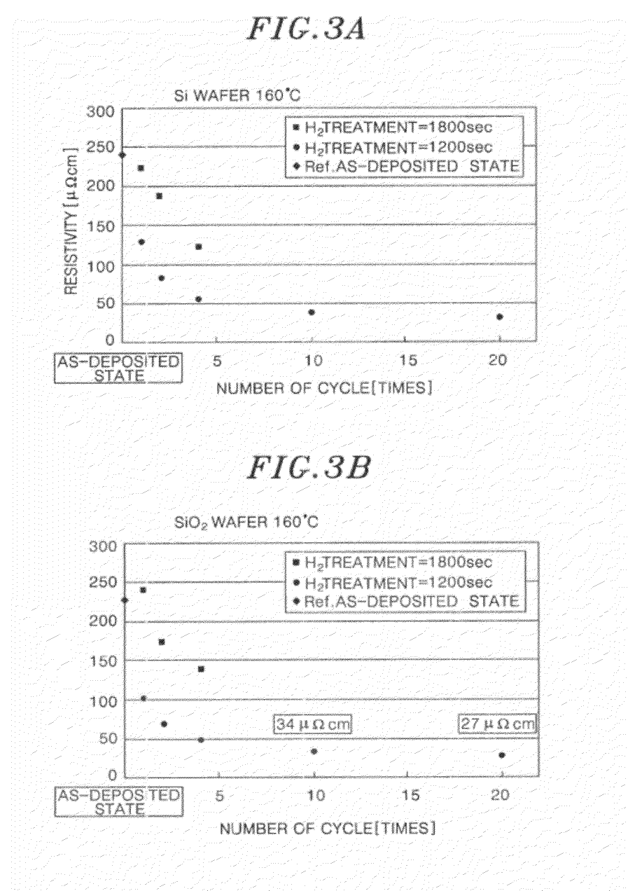

FIGS. 3A and 3B show a relationship between the number of cycles and the resistivity of a Ni film when the test was performed at about 160° C. FIG. 3A shows the result of a Si chip, and FIG. 3B shows the result of a SiO₂ wafer. As illustrated in FIGS. 3A and 3B, the resistivity is decreased as the number of cycles is increased. However, when the number of cycles exceeds four, the resistivity is slowly decreased. The effect of decreasing the resistivity was higher when the H₂ treatment time was about 1200 sec than when the H₂ treatment time was about 180 sec. Specifically, when the H₂ treatment time was about 1200 sec, the low resistivities of 27 μΩcm and 34 μΩcm were measured when the cycle was repeated twenty times and ten times, respectively.

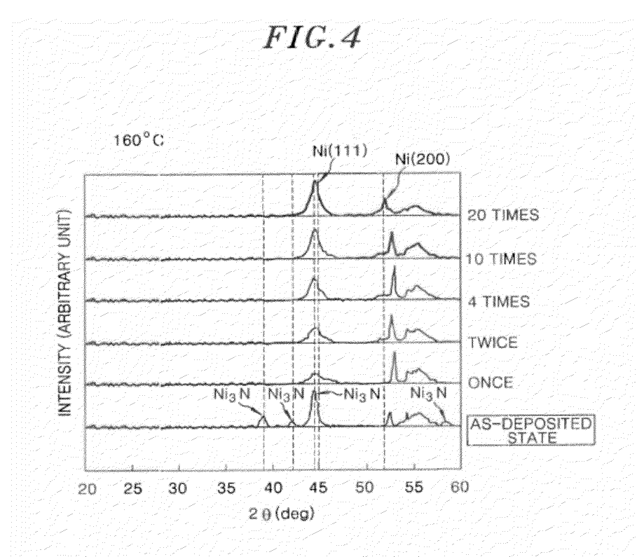

FIG. 4 shows X-ray diffraction (XRD) patterns of the Ni film formed by repeating the cycle different number of times in the test performed at about 160° C. (H₂ treatment time of 1200 sec). The vertical axis indicates the intensity of the diffraction spectrum in an arbitrary unit, and the horizontal axis indicates the angle of the diffraction spectrum. The graphs are vertically separated without being overlapped. As can be seen from FIG. 4, the peak of Ni₃N is shown in an as-deposited state of the wafer but disappears by performing the H₂ treatment.

Although the analysis is not easy because the diffraction angles (2θ) of Ni₃N and Ni are substantially overlapped near about 45°, it is assumed that the peak of Ni₃N detected in the as-deposited state is decreased by performing the H₂ treatment and that Ni₃N is converted into Ni as the number of the H₂ treatment is increased. Accordingly, the peak of Ni is increased, and thus a Ni film having a small number of impurities is obtained. The as-deposited state indicates a state of the wafer in which a film having a predetermined thickness is formed by a single film forming process without performing the H₂ treatment.

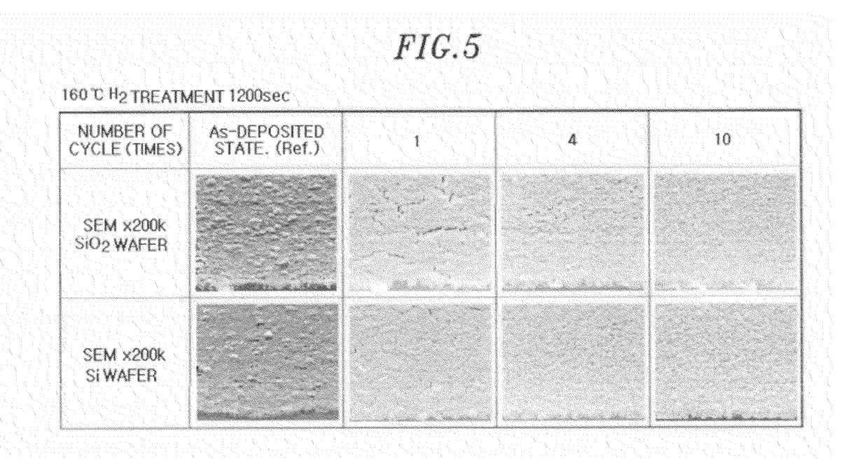

FIG. 5 shows SEM pictures of surfaces of the Ni film (H₂ treatment time of 1200 sec) formed by repeating the cycle once, four times and ten times in the test performed at about 160° C. As illustrated in the SEM pictures, microcracks are shown on the surface of the film formed by performing the cycle once. However, when the cycle was repeated four times and ten times, finer, denser and smoother films were obtained compared to the as-deposited state, and microcracks were not generated.

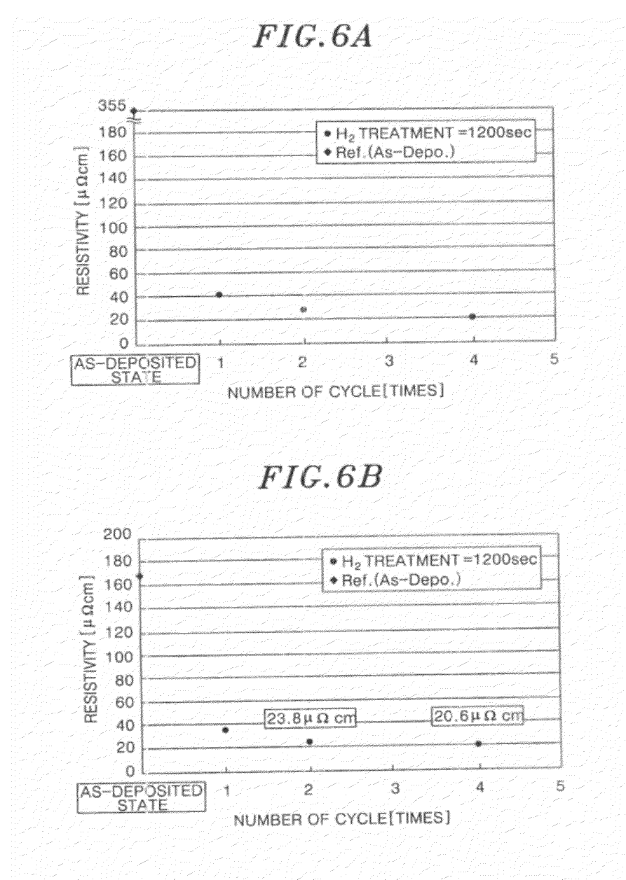

FIGS. 6A and 6B show a relationship between the number of cycles and the resistivity of the Ni film when the test was performed at about 200° C. FIG. 6A shows the result of a Si wafer, and FIG. 6B shows the result of a SiO₂ wafer. As shown in FIGS. 6A and 6B, the resistivity is decreased as the number of cycles is increased. Further, the resistivity decreasing effect was improved when the test was performed at about 200° C. compared to when the test was performed at 160° C. When the cycle was repeated twice and four times, the resistivities reach substantially saturated values, i.e., 23.8 μΩcm and 20.6 μΩcm, respectively, which are lower than the resistivity obtained when the cycle was repeated twenty times in the test performed at 160° C. This is because the impurities are reduced as the temperatures of the Ni film formation and the H₂ treatment are increased.

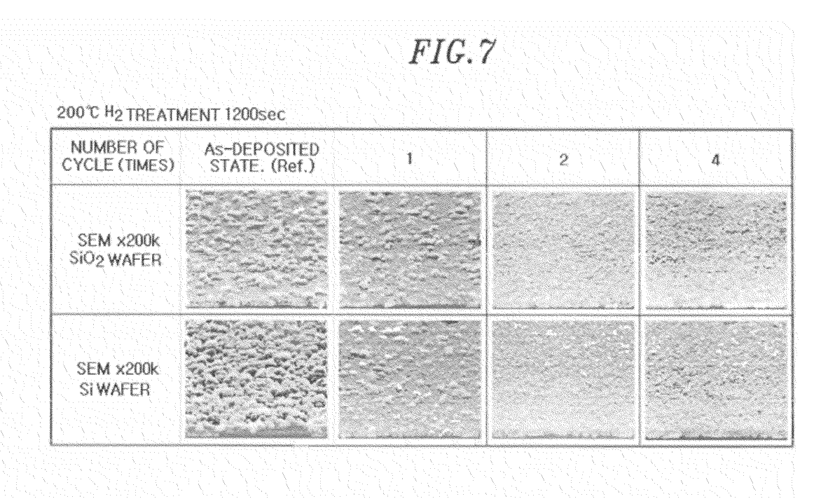

FIG. 7 shows SEM pictures of the surfaces of the Ni film formed by repeating the cycle once, twice and four times in the test performed at about 200° C. (H₂ treatment time 1200 sec). As can be seen from the SEM pictures, the surface state of the film (morphology) in the as-deposited state of the wafer is poor (especially, on the Si chip). However, a surface state of the film is slightly improved by performing the cycle once. The surface state of the film is considerably improved by performing the cycle twice. When the cycle is repeated more than twice, a finer, denser and smoother film is obtained, and microcracks are not generated.

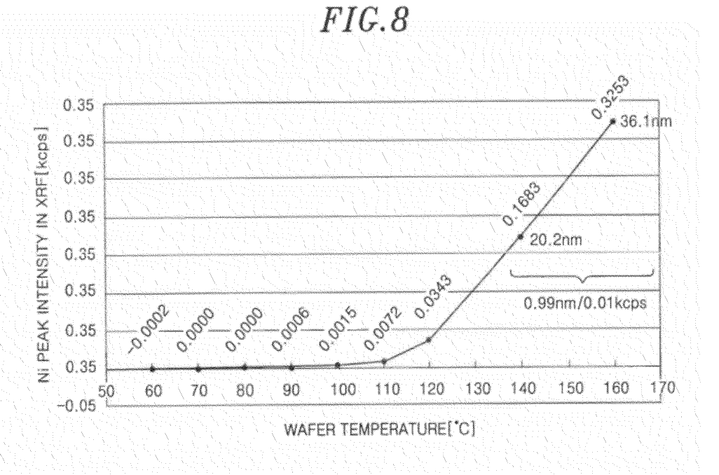

Next, the test was performed while varying the film formation temperature and the temperature of the H₂ treatment. FIG. 8 shows changes in the Ni peak intensity in the X-ray diffraction when a Ni film is formed on a SiO₂ film by repeating the cycle including film formation, purging and H₂ treatment (3 Torr, 180 sec) a predetermined number of times while varying a temperature. As can be seen from FIG. 8, the Ni peak is shown at a temperature higher than about 90° C. or above, and the temperature higher than about 90° C. or above is required for film formation. However, when the temperature is lower than about 160° C., sufficient film forming speed is not obtained. Therefore, the film formation temperature is preferably set to about 160° C. or above.

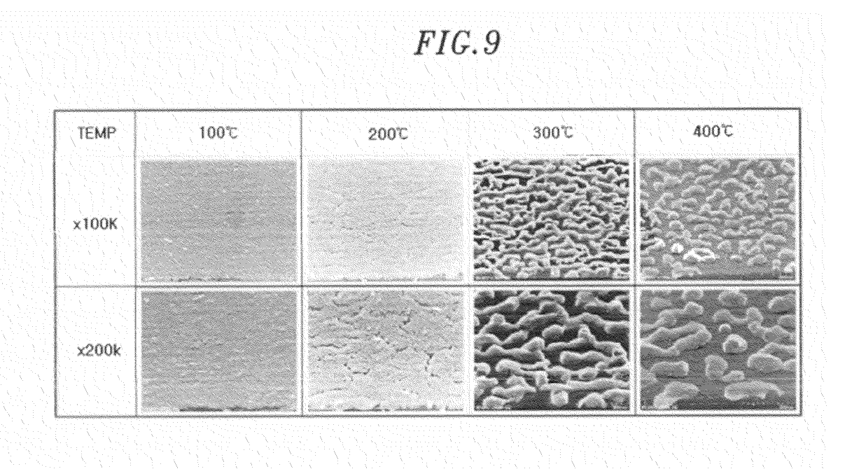

FIG. 9 shows SEM pictures of the surfaces of the Ni film formed on the SiO₂ film by repeating the cycle including film formation, purging and H₂ treatment (3 Torr, 180 sec) a predetermined number of times while setting a temperature to about 160° C., 200° C., 300° C., 400° C. As can be seen from FIG. 9, although a small number of microcracks are shown at about 200° C., the good surface state is maintained up to about 200° C. because the microcracks do not affect the film formed by repeating the film formation. However, when the temperature is higher than or equal to about 300° C., the agglomeration occurs and, thus, the continuous film is not formed even by repeating the film formation. Therefore, the film formation temperature and the H₂ treatment temperature are preferably set in the range from about 160° C. to 200° C.

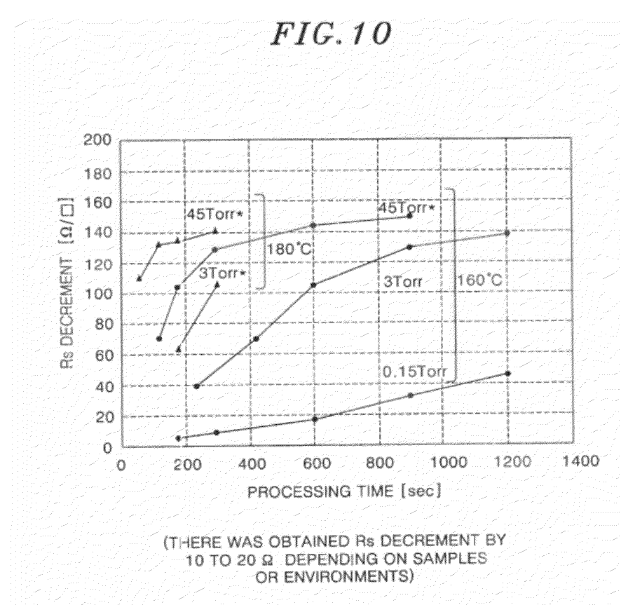

Hereinafter, description will be made on the result of examining the decrease of the resistivity Rs when a film having a thickness of about 20 nm was formed under the above-described conditions and then the H₂ treatment is performed while varying a temperature, a pressure and processing time. FIG. 10 shows a relationship between the processing time indicated by the horizontal axis and the decrement of a resistivity Rs indicated by the vertical axis when a temperature and a pressure are varied. As can be seen from FIG. 10, when the processing time is set in a range from about 180 sec to 1200 sec, the resistivity Rs is decreased regardless of the temperature/pressure.

Further, the decrement of the resistivity Rs is increased as the processing time is increased. In the test, the processing time was set to two levels of 160° C. and 180° C., and the pressure was set to three levels of 0.15 Torr, 3 Torr, and 45 Tor. The decrement of the resistivity Rs was larger at 180° C. than at 160° C. Further, the decrement of the resistivity Rs was rapidly increased as the pressure was increased from 0.15 Torr to 3 Torr, and the decrement of the resistivity Rs was further increased at the pressure of 45 Torr. This shows that a preferred pressure range is from about 3 Torr to 45 Torr, and the decrement of the resistivity Rs is maximized at about 180° C. and about 45 Torr, which were the highest temperature and the highest pressure in the test.

The present invention is not limited to the above-described embodiments, and can be variously modified. For example, in the above-described embodiments, nickel amidinate, e.g., Ni(II)(tBu-AMD)₂, is used as a film forming material. However, the film forming material is not limited thereto, and another nickel amidinate may be used.

The structure of the film forming apparatus is not limited to that described in the above embodiments. Further, the method for supplying a film forming material is not limited to that described in the above embodiments, and various methods may be employed.

Although the case in which a semiconductor wafer is used as a target substrate to be processed has been described, the target substrate may be another substrate such as a flat panel display (FPD) or the like without being limited thereto.

What is claimed is:

1. A Ni film forming method performing a cycle once or multiple times, the cycle including:
forming a nitrogen-containing Ni film on a substrate by CVD using nickel amidinate as a film formation material and at least one selected from ammonia, hydrazine and derivatives thereof as a reduction gas; and
eliminating nitrogen from the nitrogen-containing Ni film by atomic hydrogen which is generated by using as a catalyst Ni produced by supplying hydrogen gas to the nitrogen-containing Ni film.

2. The Ni film forming method of claim 1, wherein
a purge process is carried out between the forming a nitrogen-containing Ni film and eliminating nitrogen from the nitrogen-containing Ni film.

3. The Ni film forming method of claim 1, wherein
the number of cycles ranges from two to ten.

4. The Ni film forming method of claim 1, wherein
the forming a nitrogen-containing Ni film and the eliminating of nitrogen from the nitrogen-containing Ni film are performed at a same temperature.

5. The Ni film forming method of claim 4, wherein
the forming a nitrogen-containing Ni film and the eliminating nitrogen from the nitrogen-containing Ni film are performed at a temperature ranging from about 160° C. to about 200° C.

6. The Ni film forming method of claim 1, wherein
the eliminating nitrogen from the nitrogen-containing Ni film is performed for a time period ranging from about 180 sec to about 1200 sec.

7. The Ni film forming method of claim 1, wherein
the eliminating nitrogen from the nitrogen-containing Ni film is performed at a pressure ranging from about 3 Torr to about 45 Torr.

8. A computer-readable storage medium storing a computer-readable program for controlling a film forming apparatus to execute a Ni film forming method performing a cycle once or multiple times, the cycle including:
forming a nitrogen-containing Ni film on a substrate by CVD using nickel amidinate as a film formation material and at least one selected from ammonia, hydrazine and derivatives thereof as a reduction gas; and
eliminating nitrogen from the nitrogen-containing Ni film by atomic hydrogen which is generated by using as a catalyst Ni produced by supplying hydrogen gas to the nitrogen-containing Ni film.
